(19) United States
(12) Patent Application Publication
(10) Pub. No.: US 2024/0030084 A1
(43) Pub. Date: Jan. 25, 2024

(54) 3D SEMICONDUCTOR PACKAGE

(71) Applicant: Taiwan Semiconductor Manufacturing Company, Ltd., Hsinchu (TW)

(72) Inventors: Wensen Hung, Hsinchu County (TW); Tsung-Yu Chen, Hsinchu City (TW)

(73) Assignee: Taiwan Semiconductor Manufacturing Company, Ltd., Hsinchu (TW)

(21) Appl. No.: 17/873,060

(22) Filed: Jul. 25, 2022

(51) Int. Cl. H01L 23/367; H01L 23/42; H01L 23/00

(52) U.S. Cl. CPC H01L 23/367; H01L 23/42; H01L 24/32; H01L 2224/32245; H01L 25/0655

(57) ABSTRACT

A 3D semiconductor package provided herein includes a package substrate; a semiconductor package bonded to the package substrate; a heat dissipation unit attached to the semiconductor package, wherein the heat dissipation unit comprises a first heat dissipation component and a second heat dissipation component attached to the first heat dissipation component; and a first interface material disposed between the first heat dissipation component and the second heat dissipation component, wherein the first interface material is a phase change material.

### BACKGROUND

In some Three-Dimensional Integrated Circuits (3DIC), device dies are first bonded to an interposer, which is further bonded to a package substrate to form a package. The heat generated in the device dies during their operation needs to be dissipated. To dissipate the heat, the substrates of the device dies are attached to a metal lid, which helps dissipate heat, and also acts as a stiffener. Accordingly, the heat generated in the device dies is spread to the metal lid. A heat sink may be attached to the metal lid to further dissipate the heat conducted to the metal lid.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an intermediate step of a method of fabricating a 3D semiconductor package in accordance with some embodiments of the disclosure.

FIG. 2 illustrates an intermediate step of a method of fabricating a 3D semiconductor package in accordance with some embodiments of the disclosure.

FIG. 3 illustrates an intermediate step of a method of fabricating a 3D semiconductor package in accordance with some embodiments of the disclosure.

FIG. 4 illustrates an intermediate step of a method of fabricating a 3D semiconductor package in accordance with some embodiments of the disclosure.

FIG. 5A and FIG. 5B are a top view and a cross sectional view of an intermediate step of a method of fabricating a 3D semiconductor package in accordance with some embodiments of the disclosure.

FIG. 6 and FIG. 7 illustrate enlarge views of the portion 302A of the 3D semiconductor package 100 depicted in FIG. 5B in accordance with various embodiments.

FIG. 8 schematically illustrates a cross section of a 3D semiconductor package in accordance with some embodiments.

FIG. 9 schematically illustrates an enlarged portion 302B indicated in FIG. 8.

FIG. 10A and FIG. 10B schematically illustrate a top view and a cross section of a 3D semiconductor package in accordance with some embodiments of the disclosure.

FIGS. 11A to 11C schematically illustrate various embodiments of the heat dissipation component in accordance with some embodiments of the disclosure.

FIG. 12 schematically illustrates an electronic device in accordance with some embodiments of the disclosure.

FIG. 13 schematically illustrates heat dissipation paths provided by an electronic device in accordance with some embodiments of the disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The embodiments disclosed herein may be applied to various systems such as high performance computing (HPC), edge computing, cloud computing, data centers, networking, and artificial intelligence. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

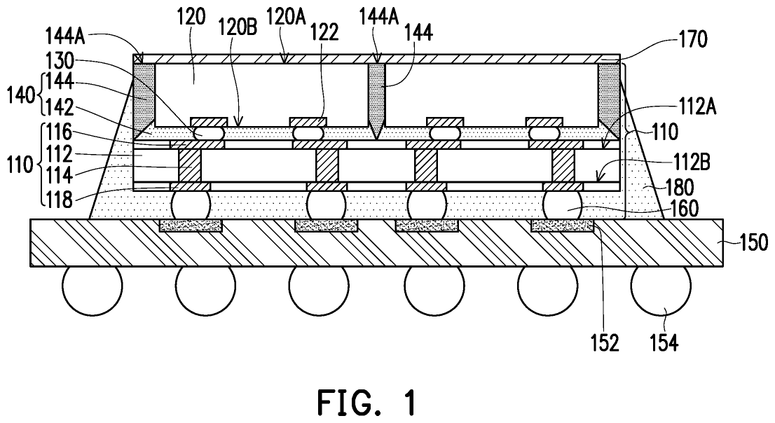

FIG. 1 illustrates an intermediate step of a method of fabricating a 3D semiconductor package in accordance with some embodiments of the disclosure. In FIG. 1, a semiconductor package 100 is provided. In some embodiments, the semiconductor package 100 includes at least a stack structure of a package component 110 and one or more semiconductor components 120 stacking on the package component 110. The package component 110 may be an interposer wafer, a package substrate strip, a device die wafer, or an alternative package component. Each of the semiconductor components 120 is stacked onto the package component 110 and includes device dies including logic circuits, memory circuits, or the like. In some embodiments, each of the semiconductor components 120 is bonded to the package component 110 through conductive connectors 130. In some embodiments, the semiconductor package 100 includes multiple semiconductor components 120 and the semiconductor components 120 are encapsulated by an encapsulation component 140 after bonded to the package component 110 to form the semiconductor package 100. In addition, the semiconductor package 100 is bonded to a package substrate 150 through conductive connectors 160. In some embodiments, the structure shown in FIG. 1 may be a Chip-on-Wafer-on-Substrate (CoWoS) structure, but the disclosure is not limited thereto. In some embodiments, a metalization layer 170 may be disposed on the semiconductor package 100.

In some embodiments, the package component 110 may include a substrate 112 such as a semiconductor substrate or a dielectric substrate. In terms of a semiconductor substrate, the substrate 112 may be formed of silicon, or another semiconductor material such as silicon germanium, silicon carbon, or the like. In some embodiments, active devices such as transistors (not shown) are formed at surface of the substrate 112 and passive devices (not shown) such as resistors and/or capacitors may also be formed integrated in the package component 110. In some embodiments, the package component 110 does not include active devices therein. In addition, the package component 110 includes through-vias 114 formed to extend from a top surface 112A of the substrate 112 to a bottom surface 112B of the substrate 112. The through-vias 114 are also referred as through-substrate vias or through-silicon vias when the substrate 112 is a silicon substrate. In some embodiments, conductive pads 116 at the top surface 112A of the substrate 112 and the conductive pads 118 at the bottom surface 112B are formed to connect opposites terminals of the through-vias 114. Accordingly, electrical connection paths extending from the top surface 112A of the substrate to the bottom surface 112B of the substrate 112 are established. The conductive connectors 130 are connected to the conductive pads 116 at the top surface 112A of the substrate 112 and the conductive connectors 160 are connected to the conductive pads 118 at the bottom surface 112B of the substrate 112.

The semiconductor components 120 are bonded to the package component 110, for example, through a flip-chip bonding. The semiconductor components 120 may be device dies including logic circuits, memory circuits, or the like. Alternatively, the semiconductor components 120 may be packages that include dies bonded to the respective interposers, package substrates, and/or the like. Two semiconductor components 120 are bonded to the package component 110 as shown in FIG. 1, but the disclosure is not limited thereto. In some embodiments, each of the semiconductor components 120 include one or more semiconductor substrates, which may be silicon substrates. In some embodiments, the top surfaces 120A of the semiconductor components 120 may be the surfaces of a semiconductor material such as silicon. In addition, conductive pads 122 may be formed at a bottom surfaces 120B of the semiconductor components 120 and connected to the conductive connectors 130.

The conductive connectors 130 include metal pillars, wherein solder caps may be, or may not be, formed on the top surfaces of the metal pillars. In some embodiments, the conductive connectors 130 may be copper pillar bump, solder bumps or composite bumps including copper posts, nickel layers, solder caps, Electro-less Nickel Immersion Gold (ENIG), Electro-less Nickel Electro-less Palladium Immersion Gold (ENEPIG), and/or the like, and/or a combination thereof. The semiconductor components 120 is bonded to the package component 110 through the conductive connectors 130, but the disclosure is not limited thereto. In some embodiments, the semiconductor components 120 is bonded to the package component 110 through an insulation-to-insulation and metal-to metal bonding so that the conductive pads 122 of the semiconductor component 120 are in contact with the conductive pads 116 of the package component 110 and the insulation layer (not shown) beside the conductive pads 122 of the semiconductor component 120 is in contact with the insulation layer beside the conductive pads 116 of the package component 110.

The encapsulation component 140 laterally encapsulates the semiconductor components 120 and disposed on the package component 110. The encapsulation component 140 may include an underfill 142 and an insulation encapsulation 144. In some embodiments, the underfill 142 fills the gaps between semiconductor components 120 and the package component 110 and encapsulates the conductive connectors 130 to protect the conductive connectors 130. The underfill 142 may include a polymer or an epoxy. The underfill 142 may also be a molding underfill, which is dispensed when the semiconductor components 120 are encapsulated. The insulation encapsulation 144 encapsulates the semiconductor components 120, for example, using compress molding, transfer molding, or the like. The insulation encapsulation 144 includes a molding compound, which includes a base material and fillers mixed in the base material. The base material may include a polymer, a resin, an epoxy, and/or the like. The fillers may be formed of spherical particles of silica, aluminum oxide, or the like. In some embodiments, the underfill 142 and the insulation encapsulation 144 are formed of the same material. In some embodiments, the underfill 142 and the insulation encapsulation 144 are formed by one single molding process to have a one-piece form so that no structural boundary between the underfill 142 and the insulation encapsulation 144 is found.

In some embodiments, the underfill 142 is formed to fill the gaps between the semiconductor components 120 and the package component 110, and subsequently, the insulation encapsulation 144 is formed to laterally surround the semiconductor component 120 and the underfill 142. In some embodiments, a curing step is performed to cure and solidify the insulation encapsulation 144 and the underfill 142, and the curing may be a thermal curing, a Ultra-Violet (UV) curing, or the like. In some embodiments, a planarization step such as Chemical Mechanical Polish (CMP) or mechanical grinding is performed after forming the insulation encapsulation 142 and the planarization step may be performed until top surfaces of the substrates in the semiconductor components 120 are not covered by the insulation encapsulation 144. Therefore, the top surfaces 120A of the semiconductor component 120 are coplanar with a top surface 144A of the insulation encapsulation 144. In addition, the insulation encapsulation 144 laterally encircles each of the semiconductor components 120.

In some embodiments, the package substrate 150 may be a Printed Circuit Board (PCB), or the like. The package substrate 150 may include electrical connectors (not shown) formed on the opposite sides of the package substrate 150 to be electrically inter-coupled through metal lines and vias (not shown) formed inside the package substrate 150 for electrically connected to an external component. For example, bonding pads 152 formed at a side of the package substrate 150 form the electric connection between the package substrate 150 and the semiconductor package 100, and external connectors 154 formed at an opposite side of the package substrate 150 form the electric connection to an external device. For example, the semiconductor package 100 is bonded to and electrically connected to the package substrate 150 through the conductive connectors 160 bonding to the conductive pads 152 on the package substrate 150. In some embodiments, an underfill 180 may be dispensed into the gap between semiconductor package 100 and package substrate 150, and cured. The underfill 180 fills the gap between the package substrate 150 and the semiconductor package 110, laterally encapsulates the conductive connectors 160 and partially covers the sidewall of the semiconductor package 110. The material of the underfill 180 may be similar to that of the underfill 142 and/or the insulation encapsulation 144.

In some embodiments, the metalization layer 170 is formed on the semiconductor package 120. The metalization layer 170 may be formed on the top surfaces of the semiconductor components 120 and thus in contact with the semiconductor substrates of the semiconductor components 120. The metalization layer 170 may be formed by deposited. The metalization layer 170 may include Ti, Cu, Ni, V, Au, or a combination thereof. In some embodiments, a thickness of the metalization layer 170 may be from 500 nanometers to 1 micrometer. A thickness of the metalization layer 170 is about 700 nanometers.

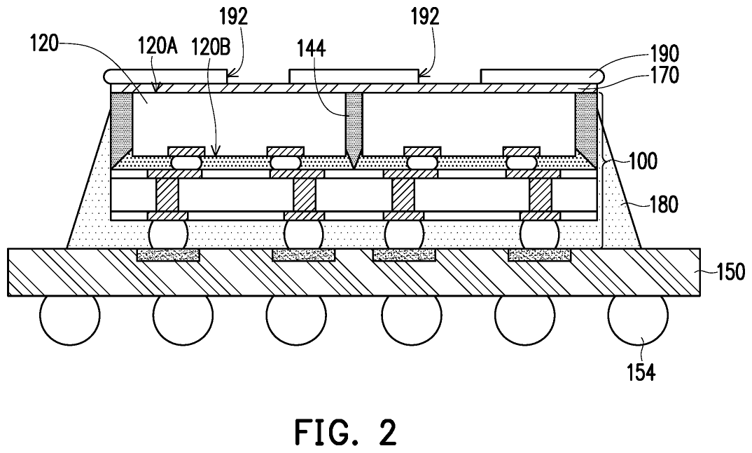

In FIG. 2, a thermal interface material (TIM) 190 is dispensed on the semiconductor package 100. The thermal interface material 190 is disposed on the metalization layer 170, but the disclosure. In some embodiments, the metalization layer 170 is omitted and the thermal interface material 190 is in contact with the top surfaces 120A of the semiconductor components 120. The thermal interface material 190 has a good thermal conductivity, which may be greater than about 2 W/m*K, and may be equal to, or higher than, about 10 W/m*K or 50 W/m*K. The thermal interface material 190 may include metallic TIM, such as indium (In) sheet or film, indium foil, indium solder, silver (Ag) paste, silver alloy or combination thereof. The thermal interface material 190 may include a polymer, resin, or epoxy as a base material, and a filler to improve its thermal conductivity. The filler may include a dielectric filler such as aluminum oxide, magnesium oxide, aluminum nitride, boron nitride, and diamond powder. The filler may also be a metal filler such as silver, copper, aluminum, or the like. The filler may be in the form of spherical particles. The thermal interface material 190 may include film-based or sheet-based material such as sheet with synthesized carbon nano-tube (CNT) structure integrated into the sheet, thermal conductive sheet with vertically oriented graphite fillers or the like.

In the embodiment, the thermal interface material 190 has openings 192. The openings 192 extend through the thermal interface material 190 in the thickness direction and the metalization layer 170 is exposed by the thermal interface material 190 at the openings 192. In other words, the metalization layer 170 at the openings 192 is not covered by the thermal interface material 190. In some embodiments, the openings 192 may be formed by removing a portion of the thermal interface material 190. A lateral dimension of each of the openings 192 may be smaller than a lateral dimension of the top surface 120A of the corresponding semiconductor component 120. In some embodiments, each of the openings 192 is completely located within the top surface 120A of the corresponding semiconductor component 120. In some embodiments, two or more openings 192 are located within an area of the top surface 120A of one semiconductor component 120. In some embodiments, the quantity of the openings 192 over one semiconductor component 120 is different from the quantity of the openings 192 over another semiconductor component 120.

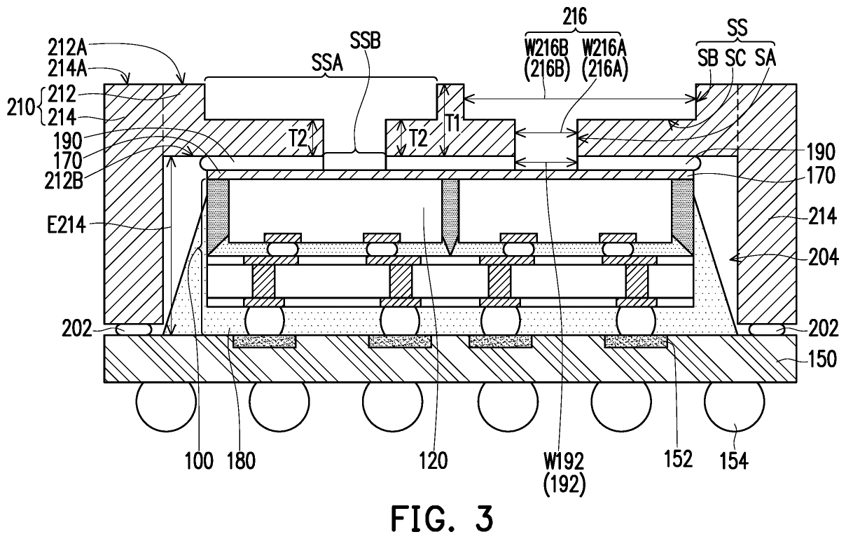

FIG. 3 illustrates an intermediate step of a method of fabricating a 3D semiconductor package in accordance with some embodiments of the disclosure. In FIG. 3, a first heat dissipation component 210 is adhered onto the package substrate 150. In some embodiments, an adhesive 202 is dispensed on the package substrate 150 and the first heat dissipation component 210 is in contact with the adhesive 202. The adhesive 202 is cured to adhere the first heat dissipation component 210 onto the package substrate 150, for example, through thermal curing. In some embodiments, the adhesive 202 includes a material similar to the thermal interface material 190. In some embodiments the adhesive 20 includes a material such as glue, epoxy, paste or the like, that has adhesion property. In some embodiments, the curing step of curing the adhesive 202 also cures the thermal interface material 170. Accordingly, the first heat dissipation component 210 is attached to the package substrate 150 and the semiconductor package 100 through the thermal interface material 170 and the adhesive 202.

The first heat dissipation component 210 is formed of a metal or a metal alloy, which has a high thermal conductivity, for example, higher than about 100 W/m*K. The material of the first heat dissipation component 210 includes a metal or a metal alloy. For example, the first heat dissipation component 210 may be formed of a metal or a metal alloy selected from Al, Cu, Ni, Co, stainless steel, and alloys thereof. The first heat dissipation component 210 is an integrated piece formed of the same homogenous metallic material in the embodiment. In alternative embodiments, the first heat dissipation component 210 may include discrete portions made of the same or different materials.

The first heat dissipation component 210 includes a plate portion 212 and a peripheral portion 214 surrounding the plate portion 212. The plate portion 212 has a top surface 212A and a bottom surface 212B opposite to the top surface 212A. The bottom surface 212B of the plate portion 212 is in contact with the thermal interface material 190 formed on the semiconductor package 100. The peripheral portion 214 has a top surface 214A that is coplanar to and co-leveled with the top surface 212A of the plate portion 212 and a bottom surface 214B opposite to the top surface 214A. The peripheral portion 214 extends exceeding the bottom surface 212B of the plate portion 212 to form a protruding wall structure to connect to the package substrate 150. The extending length E124 of the peripheral portion 214 is sufficient that the bottom surface 212B the plate portion 212 is in contact with the thermal interface material 190 on the semiconductor package 100 and the bottom surface 214B of the peripheral portion 214 is in contact with the adhesive 202 on the package substrate 150. The first heat dissipation component 210 may have a cap-like structure covering the semiconductor package 100. The peripheral portion 214 encircles the plate portion 212 to have a full ring-like pattern in a top view and is laterally spaced from the semiconductor package 100 and the underfill 180. In some embodiments, the top view pattern of the adhesive 202 follows the peripheral portion 214 to be a full ring-like pattern.

The plate portion 212 of the first heat dissipation component 210 includes a structure surface SS continuously extending between the top surface 212A of the plate portion 212 and the bottom surface 212B of the plate portion 212 to define and demarcate a through structure 216. The structure surface SS includes, for example, a first structure surface SA, a second structure surface SB and a third structure surface SC. The first structure surface SA is connected to and more adjacent to the bottom surface 212B of the plate portion 212 to define a first section 216A of the opening. The second structure surface SB is connected to and more adjacent to the top surface 212A of the plate portion 212 to define a second section 216B of the through structure 216. In addition, the third structure surface SB is connected between the first structure surface SA and the second structure surface SB. The structure surface SS has a top end SSA at the top surface 212A of the plate portion 212 and a bottom end SSB at the bottom surface 212B of the plate portion 212. The top end SSA is further away from the semiconductor package 100 than the bottom end SSB. The lateral dimension of the through structure 216 at the top end SSA is greater than the lateral dimension of the through structure 216 at the bottom end SSB. For example, in the embodiment, a lateral dimension W216A of the first section 216A is smaller than a lateral dimension W216B of the second section 216B.

In some embodiments, the lateral dimension of the through structure 216 is gradually increased from the bottom end SSB to the top end SSA in a step change. The first structure surface SA extends along a first slope, the second structure surface SB extends along a second slope and the third structure surface SC extends along a third slop. In some embodiments, the first slope and the second slope may be substantially the same and optionally parallel to the thickness direction while the third slope extends in a direction intersected and/or perpendicular to the thickness direction, such that the first structure surface SA, the second structure surface SB and the third structure surface SC define the through structure 216 as a stair-like structure. In some embodiments, the first slope, the second slope and the third slope are the same, such that the first structure surface SA, the second structure surface SB and the third structure surface SC define the through structure 216 as a taper structure. In some embodiments, the first structure surface SA, the second structure surface SB and the third structure surface SC respectively extend in various slopes, such that the first structure surface SA, the second structure surface SB and the third structure surface SC define the through structure 216 as a horn-like structure. In other words, the lateral dimension of the through structure 216 is gradually increased in a direction from the bottom end SSB to the top end SSA and the slope of the structure surface SS is optionally changed in an identical rate, a changed rate, or a combination thereof from the bottom end SSB to the top end SSA.

The first heat dissipation component 210 has one or more through structures 216 formed in the plate portion 212 and defined by the structure surface SS. The through structure 216 extends from the top surface 212A of the plate portion 212 to the bottom surface 212B of the plate portion 212, i.e., extends through the plate portion 212 in the thickness direction. In some embodiments, the through structure 216 is divided into a first section 216A and a second section 216B. The first section 216A is communicated with the second section 216B so that the through structure 216 continuously extends through the plate portion 212 in the thickness direction. The first section 216A is more adjacent to the semiconductor package 100 than the second section 216B. One end of the first section 216A, i.e. the bottom end SSB of the structure surface SS, extends to the bottom surface 212B of the plate portion 212 and the other end of the first section 216A is connected to the second section 216B. One end of the second section 216B, i.e. the top end SSA of the structure surface SS, extends to the top surface 212A of the plate portion 212 and the other end of the second section 216B is connected to the first section 216A.

In some embodiments, the lateral dimension W216A of the first portion 216 is smaller than the lateral dimension W216B of the second section 216B. The through structure 216 is positioned overlapping the area of one corresponding opening 192 of the thermal interface material 190. In some embodiments, the lateral dimension W216A of the first section 216A is not smaller than the lateral dimension W192 of the opening 192 formed in the thermal interface material 190. In some embodiments, the area of the opening 192 is completely located within the area of the first section 216A and the area of the first section 216A is completely located within the area of the second section 216B. Accordingly, the portion of the metalization layer 170 exposed by the opening 192 is exposed at the through structure 216 without covering by the thermal interface material 190 and the first heat dissipation component 210.

In some embodiments, the plate portion 212 of the first heat dissipation component 210 has a first thickness T1 at regions outside the through structures 216 and a second thickness T1 at regions overlapping the through structures 216. The first thickness T1 is identical to a distance from the top surface 212A to the bottom surface 212B and the second thickness T2 is smaller than the first thickness T1. In some embodiments, the second thickness T2 is a changed thickness or an identical thickness smaller than the first thickness T1. In some embodiments, the second thickness T2 is gradually changed in a lateral direction from the top end SSA to the bottom end SSB. In some embodiments, the through structures 216 is defined by the edge outline of the thinned portion of the first heat dissipation component 210.

In some embodiments, the first heat dissipation component 210 is bonded and/or attached to the package substrate 150 through the adhesive 202 and bonded and/or attached to the semiconductor package 100 through the thermal interface material 190. The peripheral portion 214 of the first heat dissipation component 210 is spaced from the semiconductor package 100. In some embodiments, a space 204 is encircled by the package substrate 150 and the first heat dissipation component 210 and the space 204 laterally surrounds the semiconductor package 100. In some embodiments, the thermal interface material 190 is disposed to fully encircle the openings 192 and the thermal interface material 190 is in direct contact with the first heat dissipation component 210 and the metalization layer 170 on the semiconductor packages 100. Therefore, the space 204 is completed sealed without communicated with the through structure 216. In some embodiments, the thermal interface material 190 fills the gaps between first heat dissipation component 210 and the metalization layer 170 and isolated the space 204 from the space/hole surrounded by the through structure 216. In some embodiments, the space 204 is optionally filled with insulation material, gas, or the like, or vacuumed.

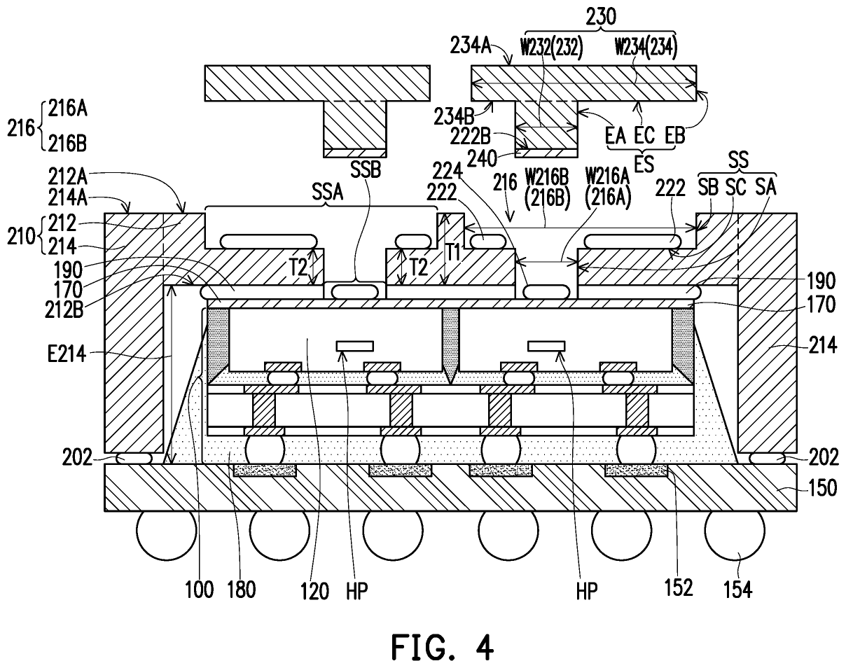

FIG. 4 illustrates an intermediate step of a method of fabricating a 3D semiconductor package in accordance with some embodiments of the disclosure. In FIG. 4, a first interface material 222 is dispensed on the first dissipation component 210. The first interface material 222 is in a liquid and/or gel form and dispensed on the third structure surface SC of the through structure 216. In some embodiments, the third structure surface SC between the first structure surface SA and the second structure surface SB is oriented to maintain the first interface material 222. In some embodiments the third structure surface SC is more horizontal than the first structure surface SA and the second structure surface SB. In some embodiments, the third structure surface SC is a curved surface that has a middle section more adjacent to the semiconductor package 100 than peripheral section to hole the first interface material 222. In some embodiments, the viscosity and/or the amount of the first interface material 222 dispensed on the first heat dissipation component 210 is optimized that the first interface material 222 does not spread towards the exposed metalization layer 170. Accordingly, the portion of the metalization layer 170 exposed at the openings 192 is not covered by the first interface material 222.

In some embodiments, the first interface material 222 include a phase change material that involves different properties at different temperature ranges. In some embodiments, the first interface material 222 is softer and/or easier to compress at a first temperature range higher than at a second temperature range. For example, the first interface material 222 is softer and/or easier to compress at a temperature ranged from 40° C. to 60° C. than at a room temperature, but the disclosure is not limited thereto. In some embodiments, the first interface material 222 includes thermal plastic material. In some embodiments, the first interface material 222 includes polymer-based gel, thin metallic alloy pad formed by indium, bismuth and tin alloy metal, polymer based elastomer with thermally conductive filler or silicone based polymer matrix or a combination thereof.

In FIG. 4, a second interface material 224 is further dispensed on the semiconductor package 100 in the opening 192 of the thermal interface material 190. The second interface material 224 is of different material and property from the first interface material 222. The second interface material 224 involves good thermal conduction property so as to serve as a thermal interface material. In some embodiments, the second interface material 224 has a thermal conductivity similar to or greater than the thermal interface material 190, for example, greater than about 2 W/m*K, and may be equal to, or higher than, about 10 W/m*K or 50 W/m*K. In some embodiments, the second interface material 224 includes metallic TIM, such as indium (In) sheet or film, indium foil, indium solder, silver (Ag) paste, silver alloy or combination thereof. In some embodiments, the second interface material 224 includes solder material, In, Cu, Bismuth, tin, rhodium, palladium, platinum, silver, gold, gallium or a combination thereof. In some embodiments, the second interface material 224 include a liquid-formed metal, such as alloy of indium, bismuth, tin, gallium, rhodium or a combination thereof. The second interface material 224 is in contact with the metalization layer 170, but the disclosure is not limited thereto. In some embodiments, the metalization layer 170 is optionally omitted so that the thermal interface material 190 and the second interface material 224 are in direct contact with the semiconductor package 100 and particularly, in direct contact with the semiconductor substrate of the semiconductor component 120 in the semiconductor package 100.

In addition, one or more second heat dissipation components 230 are provided and inserted to the through structures 216 of the first heat dissipation component 210. In some embodiments, a quantity of the second heat dissipation components 230 is corresponding to a quantity of the through structures 216 formed in the first heat dissipation component 210. For example, the quantity of the second heat dissipation components 230 is the same as the quantity of the through structures 216 so that each of the second heat dissipation components 230 is inserted in one of the through structures 216 in the subsequent step.

The second heat dissipation components 230 are inserted in the through structures 216 of the first heat dissipation component 210 and have a thermal conductivity greater than the first heat dissipation component 210. In some embodiments, the thermal conductivity of the second heat dissipation components 230 is greater than 200 W/m*K, for example, 800 W/m*K, greater than 1,000 W/m*K or higher. In some embodiments, the second heat dissipation components 230 may include a super conductive material such as silver diamond (AgD), diamond-like carbon (DLC), silver diamond composite, copper diamond composite, aluminum diamond composite, alloy42 diamond composite, carbon metal composite, the like or a combination thereof. Accordingly, the second heat dissipation component 230 provides a heat dissipation highway for dissipating the heat from the semiconductor components 120 of the semiconductor package 100.

The second heat dissipation components 230 may have structures compensating or corresponding to the through structure 216 of the first heat dissipation components 210. Each of the second heat dissipation components 230 includes a first portion 232 and a second portion 234. The second portion 234 has a top surface 234A and a bottom surface 234B opposite to the top surface 234A and the top surface 234A is also served as the top surface 230A of the second heat dissipation component 230. The first portion 232 is connected to the second portion 234 and protruded from the bottom surface 234B of the second portion 234. The second heat dissipation component 230 is oriented that the first portion 232 is more adjacent to the semiconductor package 100 than the second portion 234. The first portion 232 and the second portion 234 are formed in a one-piece form and thus there is not structural boundary between the first portion 232 and the second portion 234. The first portion 232 and the second portion 234 refer to different regions of the second heat dissipation component 230 rather than different parts that are individual pieces. For descriptive purpose, the following descriptions mainly describe one of the second heat dissipation components 230 and the corresponding one of the through structures 216 in the first heat dissipation component 210.

The second heat dissipation component 230 has a structure corresponding to the first section 216A and second section 216B of the corresponding through structure 216 formed in the first heat dissipation component 220. For example, the shape of the first portion 232 is corresponding to and optionally compensates the first section 216A of the through structure 216 and the shape of the second portion 224 is corresponding to and optionally compensates the second section 216B of the through structure 216. The first portion 232 has a lateral dimension W232 smaller than a lateral dimension W234 of the second portion 234. The lateral dimension W232 of the first portion 232 is proximate to but not greater than the lateral dimension W216A of the first section 216A of the through structure 216. Similarly, the lateral dimension W234 of the second portion 234 is proximate to but not greater than the lateral dimension W216B of the second section 216B of the through structure 216. Accordingly, in some embodiments, the second heat dissipation component 230 is inserted in the through structure 216 of the first heat dissipation component 210 to form a lid having a substantially flat top surface.

In some embodiments, a metalization layer 240 is formed at the bottom of the second heat dissipation component 220 and specifically formed at the bottom surface 222B of the first portion 222. The metalization layer 240 may be formed using the material and the method of forming the metalization layer 170 on the semiconductor package 100. The metalization layer 240 and the metalization layer 170 facilitate the connection between the second heat dissipation component 220 to the semiconductor package 120. In some embodiments, one or both of the metalization layer 240 and the metalization layer 170 are omitted. In some embodiments, the thickness of the metalization layer 240 is from about 500 nanometers to about 1 micrometer.

In some embodiments, the second heat dissipation component 220 includes a first embedded surface EA, a second embedded surface EB and a third embedded surface EC. In some embodiments, the bottom surface 234B of the second portion 234 is the third embedded surface EC. The first embedded surface EA laterally surrounds the first portion 232, the second embedded surface EB laterally surrounds the second portion 234, and the third embedded surface EC extends between the first embedded surface EA and the second embedded surface EB. In some embodiments, the first embedded surface EA is the sidewall of the first portion 222 and the second embedded surface EB is the sidewall of the second portion 224. The first embedded surface EA is arranged corresponding to the first structure surface SA of the through structure 216. For example, the first embedded surface EA may have the same slope as the first structure surface SA. Similarly, the second embedded surface EB is arranged corresponding to the second structure surface SB to have substantially the same slope of the second structure surface SB. The third embedded surface is arranged corresponding to the third structure surface SC as well. Accordingly, the first embedded surface EA, the second embedded surface EB and the third embedded surface EC form an embedded surface ES corresponding to and/or compensating to the structure surface SS of the through structure 216. For example, the embedded surface ES may substantially conform to the structure surface SS of the through structure 216.

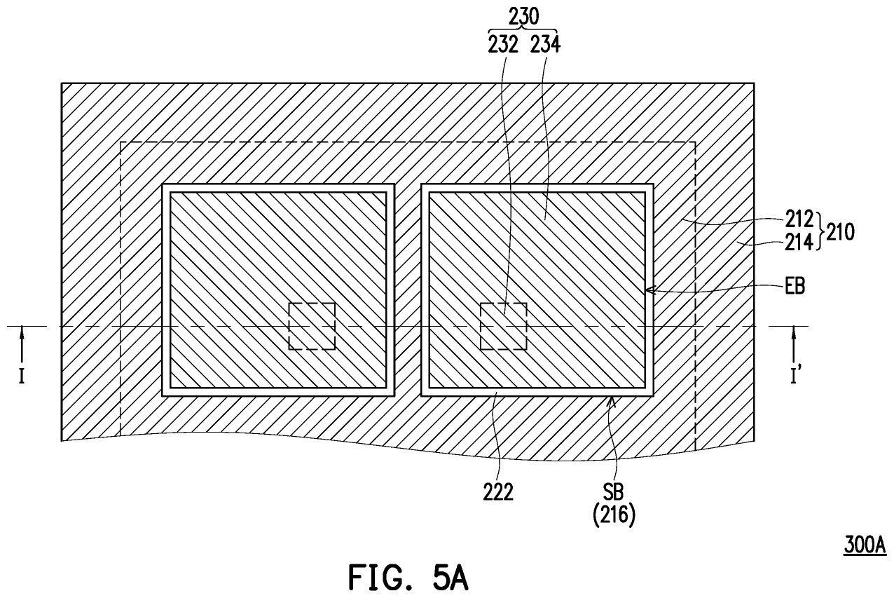

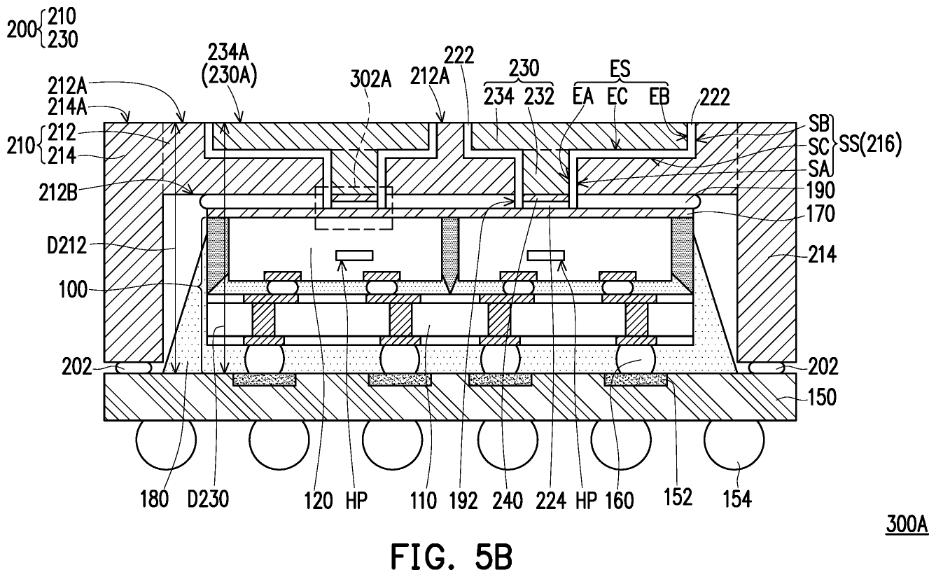

FIG. 5A is a top view of an intermediate step of a method of fabricating a 3D semiconductor package in accordance with some embodiments of the disclosure. In FIG. 5A, the second heat dissipation component 230 is attached to the semiconductor package 100 and the first heat dissipation component 210. The boundary between the plate portion 212 and the peripheral portion 214 is presented by dash line in FIG. 5A since the boundary is not seen from the top view. In addition, the first portion 232 of the second heat dissipation component 230 is also presented by dash line in FIG. 5A due to the same reason. From the top view, i.e. FIG. 5A, the first heat dissipation component 210, the first portion 232 of the second heat dissipation component 230 and the second portion 234 of the second heat dissipation component 230 respectively have a rectangular shape, but the disclosure is not limited thereto. In some embodiments, the top view patterns of the first portion 232 and the second portion 234 are determined based on various design requirements. In addition, the area of the second portion 234 is greater than the area of the first portion 232 in the top view of FIG. 5A. In some embodiments, from the top view of FIG. 5A, the first portion 232 is fully surrounded by the second portion 234. In some embodiments, the locations of the first portion 232 and the second portion 234 is determined based on the design of the product.

FIG. 5B shows the cross-sectional view of the 3D semiconductor package 300A taken along the line I-I of FIG. 5A. As shown in FIG. 5B, the second heat dissipation component 220 is inserted in the through structure 216 of the first heat dissipation component 210 to form a heat dissipation unit 200. Accordingly, a 3D semiconductor package 300A is obtained. The 3D semiconductor package 300A includes a package substrate 150, a semiconductor package 100 bonded onto the package substrate 150, and a heat dissipation unit 200 attached to the package substrate 150 and the semiconductor package 100. The semiconductor package 100 includes one or more semiconductor components 120 with circuitry structures constructed by semiconductor elements such as transistors therein. The semiconductor package 100 is bonded to and electrically connected to the package substrate 150. The 3D semiconductor package 300A is electrically connected to an external component through the external connectors 154. The one or more semiconductor components 120 of the semiconductor package 100 would generate heat during operation and the heat dissipation unit 200 covering the semiconductor package 100 protects the semiconductor package 100 and provides heat dissipation for the semiconductor package 100. Accordingly, the performance of the semiconductor package 100 is ensured since the heat generated during operation is dissipated efficiently.

The semiconductor package 100 includes at least a stack of a package component 110 and one or more semiconductor components 120. As described in above, the package component 110 is an interposer component and forms electric transmission path between the semiconductor components 120 and the package substrate 150 in the thickness direction. The semiconductor package 100 further includes the conductive connectors 130 and the encapsulation component 140 as described in FIG. 1. For example, the semiconductor components 120 are bonded and electrically connected to the package component 110 through the conductive connectors 130, and the encapsulation component 140 includes the underfill 142 encapsulating the conductive connectors 130 and the insulation encapsulation 144 laterally encapsulating the semiconductor components 120 on the package component 110. In addition, referring to FIG. 1, the semiconductor package 100 is bonded to the package substrate 150 through the conductive connectors 160 and an underfill 180 is disposed between the semiconductor package 100 and the package substrate 150. The metalization layer 170 is disposed on the semiconductor package 100 and is in direct contact with the one or more semiconductor components 120.

The heat dissipation unit 200 is attached to the package substrate 150 through the adhesive 202 and includes the first heat dissipation component 210 and the second heat dissipation component 230. The first heat dissipation component 210 is attached to the semiconductor package 100 through the thermal interface material 190. In addition, the second heat dissipation component 230 is attached to the first heat dissipation component 210 through the first interface material 222 and the second heat dissipation component 230 is attached to the semiconductor package 100 through the second interface material 224. The first heat dissipation component 210 and the second heat dissipation component 230 have different thermal conduction properties. The heat generated during the operation of the semiconductor package 100 is able to be released from the heat dissipation unit 200 at various dissipation rate. In some embodiments, the second heat dissipation component 230 has a thermal conductivity greater than the first heat dissipation component 210 so that the heat dissipation rate at regions of the openings 192 is greater than at other regions. In some embodiments, the semiconductor package 100 optionally includes one or more hot spot regions HP at which the heat during operation of the semiconductor package 100 is generated more than at other regions. The hot spot region HP is optionally determined during the design of the circuitry structure. Accordingly, the regions of the openings 192 are planned at the one or more hot spot regions HP when design the 3D semiconductor package 300A. The second heat dissipation components 230 provides a heat dissipation highway to efficient dissipate the heat from the hot spot regions HP. The performance of the semiconductor package 100 is ensured and the lifetime of the semiconductor package 100 is prolonged since the heat generated during operation is dissipated efficiently and particularly, the heat dissipation of the hot spot regions HP is enhanced by the second heat dissipation component 230.

As shown in FIG. 5A and FIG. 5B, the first interface material 222 is disposed between the first heat dissipation component 210 and the second heat dissipation component 230. Specifically, the first interface material 222 extends along the through structure 216 of the first heat dissipation component 210. The first interface material 222 continuously extend between the first structure surface SA and the first embedded surface EA, between the second structure surface SB and the second embedded surface EB, and between the third structure surface CA and the third embedded surface EC. In some embodiments, the first interface material 222 is not overlapped with the second interface material 224. In some embodiments, the embedded surface ES including the first embedded surface EA, the second embedded surface EB and the third embedded surface EC is surrounded by the first interface material 222 and is embedded in the through structure 216 defined by the structure surface SS including the first structure surface SA, the second structure surface SB and the third structure surface SC.

The second interface material 224 is disposed between the second heat dissipation component 230 and the semiconductor package 100. The metalization layer 170 is disposed on the semiconductor package 100 and the metalization layer 240 is disposed on the first portion 232 of the second heat dissipation component 230. The second interface material 224 is in contact with the metalization layer 170 and the metalization layer 240. The metalization layer 170 and the metalization layer 240 include Ti, Cu, Ni, V, Au, or a combination thereof. The metalization layer 170 and the metalization layer 240 improve the connection between the second heat dissipation component 240 and the semiconductor package 100 since the material of the semiconductor components 120 in the semiconductor package 100, such as silicon, is quite different from the material of the second heat dissipation component 230, such as super thermal conductive materials. In some embodiments, the metalization layer 170 and the metalization layer 240 are optionally omitted and the second interface material 224 is in direct contact with the first portion 232 of the second heat dissipation component 230 and the semiconductor components 120 of the semiconductor package 100.

Referring to FIG. 5B, the top surface 230A of the second heat dissipation component 230 is higher than or coplanar to the top surface 212A of the plate portion 212 of the first heat dissipation component 210. The top surface 230A of the second heat dissipation component 230 is higher than the top surface 212A of the plate portion 212 of the first heat dissipation component 210 in FIG. 5B, but in alternative embodiments, the top surface 230A of the second portion 230 of the second heat dissipation component 230 is optionally coplanar with the top surface 212A of the plate portion 212 of the first heat dissipation component 210. In some embodiments, a distance D230 from the top surface 230A to the package substrate 150 is not smaller than a distance D212 from the top surface 212A to the package substrate 150. In some embodiments, the first interface material 222 includes a phase change material to involve a rigid state and a easier to be compressed or a softer state at different temperature ranges. For example, the first interface material 222 involves the soft state at a temperature of 40° C. to 60° C. and involves the rigid state at a room temperature, but the disclosure is not limited thereto. In some embodiments, the first interface material 222 and/or the second interface material 224 include an easier to be compressed or a softer state so that the top surface 230A may be moved from a level higher than the top surface 212A to a level of the top surface 212A when a stress directing to the package substrate 150 is applied to the second heat dissipation component 230.

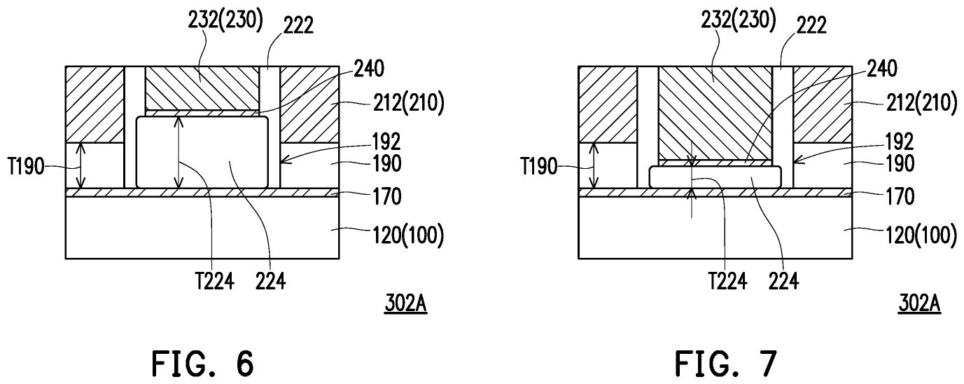

FIG. 6 and FIG. 7 illustrate enlarge views of the portion 302A of the 3D semiconductor package 100 depicted in FIG. 5B in accordance with various embodiments. As shown in FIG. 6 and FIG. 7, the first interface material 222 is disposed between the first heat dissipation component 210 and the second heat dissipation component 230. The first interface material 222 is optionally disposed between the second interface material 224 and the thermal interface material 190. The second interface material 224 is disposed between the second heat dissipation component 230 and the semiconductor package 100 and particularly between the first portion 232 of the second heat dissipation component 230 and the semiconductor component 120 of the semiconductor package 100. In some embodiments, the metalization layer 170 is disposed on the semiconductor package 100, the metalization layer 240 is disposed on the first portion 232 of the second heat dissipation component 230 and the second interface material 224 is in direct contact with the metalization layer 170 and the metalization layer 240. In some embodiments, the thickness T224 is about 3 micrometers and the thickness T190 is about 10 micrometers. In FIG. 6, the thickness T224 of the second interface material 224 is greater than the thickness T190 of the thermal interface material 190. In FIG. 7, the thickness T224 of the second interface material 224 is smaller than the thickness T190 of the thermal interface material 190.

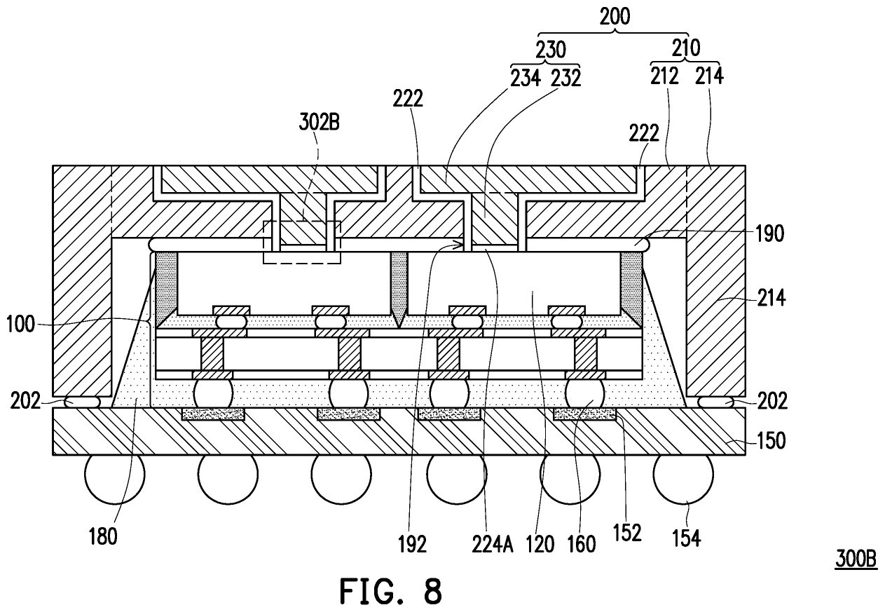

FIG. 8 schematically illustrates a cross section of a 3D semiconductor package in accordance with some embodiments. A 3D semiconductor package 300B is similar to the 3D semiconductor package 300A depicted in FIG. 5B and the same reference numbers indicated in the two embodiments refer the same components. The 3D semiconductor package 300B includes mainly the package substrate 150, the semiconductor package 100 bonded to the package substrate 150, and the heat dissipation unit 200 attached to the package substrate 150 and the semiconductor package 100. The semiconductor package 100 is bonded to the package substrate 150 through the conductive connectors 160. The heat dissipation unit 200 is attached to the package substrate 150 through the adhesive 202. The heat dissipation unit 200 includes the first heat dissipation component 210 and the second heat dissipation component 230 attached to the first heat dissipation component 210. The first heat dissipation component 210 is attached to the semiconductor package 100 through the thermal interface material and the second heat dissipation component 230 is attached to the semiconductor package 100 through an second interface material 224A. The 3D semiconductor package 300B is different from the 3D semiconductor package 300A in that the metalization layer 170 and the metalization layer 240 depicted in FIG. 5B are omitted. The structure, disposition, material, or other features of the package substrate 150, the semiconductor package 100, the heat dissipation unit 200 described in the previous embodiments are incorporated in the embodiment of FIG. 8 and are not reiterated.

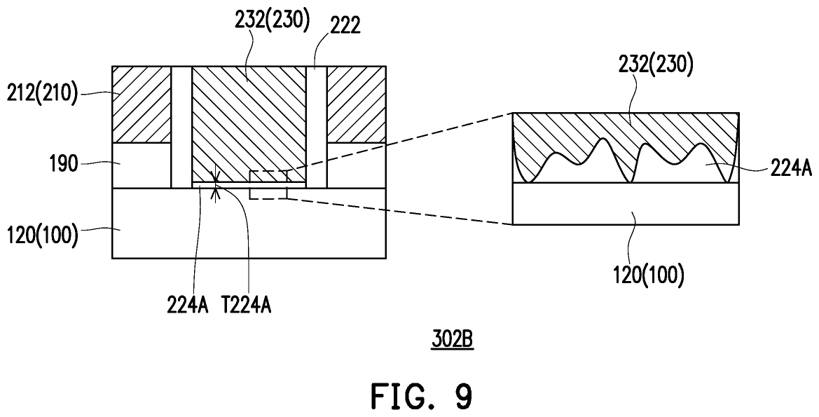

FIG. 9 schematically illustrates an enlarged portion 302B indicated in FIG. 8. Referring to FIG. 8 and FIG. 9, the second interface material 224A includes a liquid interface material. The second interface material 224A includes a material such as solder material, In, Cu, Bismuth, tin, rhodium, palladium, platinum, silver, gold, gallium or a combination thereof. The second interface material 224A is in a liquid form before being cured. In some embodiments, during fabricating the 3D semiconductor package 300B, the material for the second interface material 224A in the liquid form is dispensed on the semiconductor component 120 of the semiconductor package 100 and the second heat dissipation component 230 is attached to the semiconductor component 120 through the material for the second interface material 224A in the liquid form. Subsequently, a cure process is performed to cure the material for the second interface material 224A in the liquid form and thus the second interface material 224A is formed.

The second interface material 224A is in direct contact with the second heat dissipation component 230 and the semiconductor package 120. In addition, the thermal interface material 190 is also in direct contact with the semiconductor component 120 and the first heat dissipation component 212 since the metalization layers 190 and 240 are omitted in the embodiment. The second interface material 224A is formed from a thermal interface material in liquid form and thus as shown in FIG. 9, the second interface material 224A fills the rough surface of the second heat dissipation component 230. Accordingly, the attachment and the heat transmission between the second heat dissipation component 230 and the semiconductor component 120 are desirable. In addition, the thickness T224A of the second interface material 224A is small, for example, smaller than 10 μm, or 2 μm-10 μm. In some embodiments, the metalization layer 240 depicted in FIG. 5B may be applied in the 3D semiconductor package 300B. In other words, the metalization layer 240 is optionally disposed between the second interface material 224A and the second heat dissipation component 230 while the second interface material 224A is in direct contact with the semiconductor component 120.

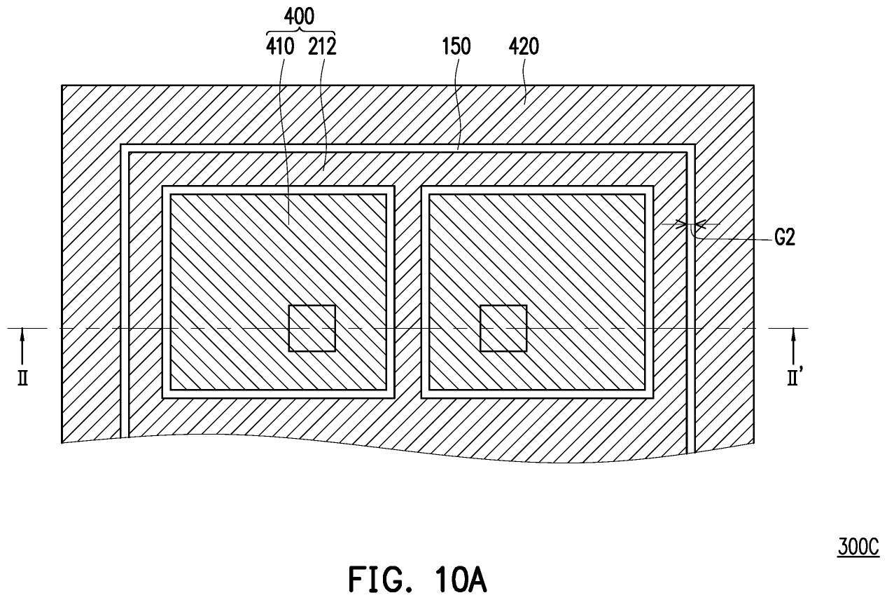

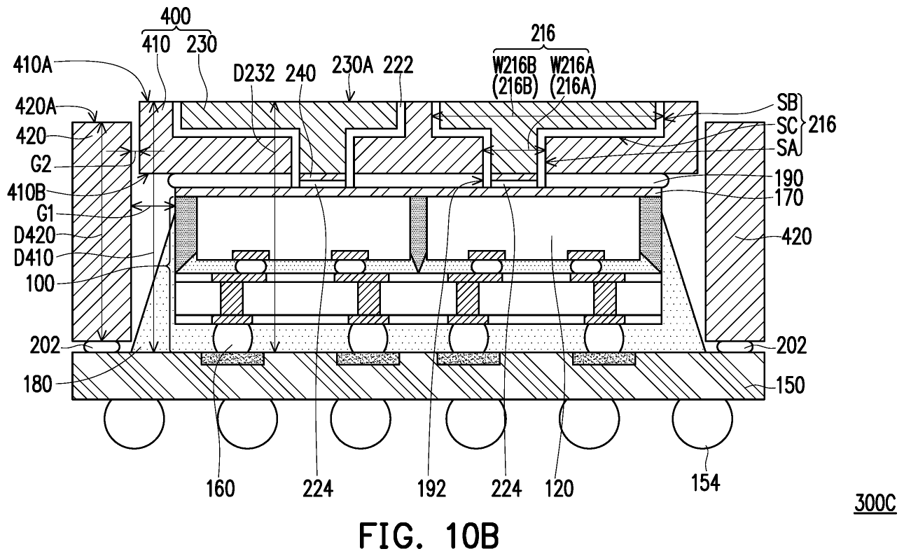

FIG. 10A and FIG. 10B schematically illustrate a top view and a cross section of a 3D semiconductor package in accordance with some embodiments of the disclosure. FIG. 10B show the cross section of a 3D semiconductor package 300C taken along the line II-II depicted in FIG. 10A. The 3D semiconductor package 300C includes a semiconductor package 100, a package substrate 150, a first heat dissipation component 410, a second heat dissipation component 230, and a peripheral component 420. The semiconductor package 100 is bonded to the package substrate 150 through conductive connectors 160, and external connectors 154 are disposed at an external surface of the package substrate 150. The first dissipation component 410 is attached to the semiconductor package 100 through a thermal interface material 190 and the second heat dissipation component 230 is attached to the first heat dissipation component 410 through a first interface material 222 and attached to the semiconductor package 100 through a second interface material 224. In addition, the peripheral component 420 is attached to the package substrate 150 through an adhesive 202. In the embodiment, the semiconductor package 100, the package substrate 150, the external connectors 154, the conductive connectors 160, the thermal interface material 190, the adhesive 202, the first interface material 222, the second interface material 224, and the second heat dissipation component 230 are similar to or the same as those depicted in the previous embodiments and thus the descriptions for these components in previous embodiments is applicable in the embodiment.

The first heat dissipation component 410 is a plate-like component and has one or more through structures 216. The first heat dissipation component 410 has a top surface 410A and a bottom surface 410B opposite to the top surface 410A. Each of the through structures 216 extends continuously from the top surface 410A to the bottom surface 410B. Each of the through structures 216 has a first structure surface SA connected to the bottom surface 410A, a second structure surface SB connected to the top surface 410B and a third structure surface SC connected between the first structure surface SA and the second structure surface SB. The first structure surface SA defines a first section 216A of the through structure 216, the second structure surface SB defines a second section 216B of the through structure 216 and the third structure surface SC extends between the first section 216A and the second section 216B. The first section 216A more adjacent to the semiconductor package 100 has a lateral dimension W216A smaller than a lateral dimension W216B of the second section 216B. Each of the through structures 216 accommodates one of the second heat dissipation components 230 so that the second heat dissipation component 230 is at least partially embedded in the through structure 216. Specifically, the through structure 216 formed in the first heat dissipation component 410 is similar to the plate portion 212 of the first heat dissipation component 210 depicted in the previous embodiments. In some embodiments, the first heat dissipation component 410 is formed by removing and/or omitting the peripheral portion 214 of the first heat dissipation component 210 in the previous embodiments.

The second heat dissipation component 230 is attached to the first heat dissipation component 410 by inserted in the through structure 216 of the first heat dissipation component 410 to form a heat dissipation unit 400. The material of the first heat dissipation component 410 includes the material of the first heat dissipation component 210 depicted in the previous embodiments. In some embodiments, the second heat dissipation component 230 has better heat dissipation property than the first heat dissipation component 410. In addition, the second heat dissipation component 230 is attached to the semiconductor package 100 through the second interface material 224 that allows an efficient heat transmission between the second heat dissipation component 232 and the semiconductor component 120 of the semiconductor package 100. As such, the second heat dissipation component 410 provides the heat dissipation unit 400 a heat dissipation highway for the semiconductor package 100. In some embodiments, the first section 216A of the through structure 216 is arranged at the location corresponding to the hot spot region of the semiconductor component 120.

The peripheral component 420 has a ring-like shape in the top view as shown in FIG. 10A. The peripheral component 420 laterally surrounds the semiconductor package 100 with a gap G1 between the peripheral component 420 and the semiconductor package 100. In addition, the peripheral component 420 is spaced from the first heat dissipation component 410 by a gap G2. Therefore, the first heat dissipation component 410 is independent from the peripheral component 420 in structure. The peripheral component 420 includes a material selected from the materials for forming the first heat dissipation component 410. In some embodiments, the peripheral component 420 is of the same material as the first heat dissipation component 410, but the disclosure is not limited thereto. In some embodiments, the top surface 420A of the peripheral component 420 is not higher than the top surface 410A of the first heat dissipation component 410. For example, a distance D410 from the top surface 410A to the package substrate 150 is equal to or greater than a distance D420 from the top surface 420A to the package substrate 150. Accordingly, the top surface 410A may be leveled higher than the top surface 420A.

In some embodiments, a metallization layer 214 is formed on top of the semiconductor package 100, a metallization layer 240 is form on bottom of the second heat dissipation component 230 and the second interface material 224 is attached and in direct contact between the metallization layer 214 and the metallization layer 240. In some embodiments, the second interface material 224 is replaced by the second interface material 224A depicted in FIG. 8 and FIG. 9 and the metallization layer 214 and the metallization layer 240 are optionally omitted. Accordingly, the second interface material 224 is optionally in direct contact with the semiconductor component 120 of the semiconductor package 100, the second heat dissipation component 230, or both.

In some embodiments, the first interface material 222 extends in the gap between the first heat dissipation component 410 and the second heat dissipation component 230. The first interface material 222 has a heat transmission property less efficient than the second interface material 224, and has a temperature dependent property. In some embodiments, the first interface material 224 has a softer and/or easier to be compressed state at a higher temperature range and a rigid state at a lower temperature range. The higher temperature range is optionally from 40° C. to 60° C. and the lower temperature range is room temperature. The distance D230 form the top surface 230A of the second heat dissipation component 230 to the package substrate 150 is changeable due to the state change of the first interface material 222. In some embodiments, the distance D230 from the top surface 230A of the second heat dissipation component 230 to the package substrate 150 is not smaller than the distance D410 from the top surface 410A to the first heat dissipation component 410 to the package substrate 150. In some embodiments, the top surface 230A and the top surface 410A are coplanar. In some embodiments, the distance D230 is equal to the distance D410.

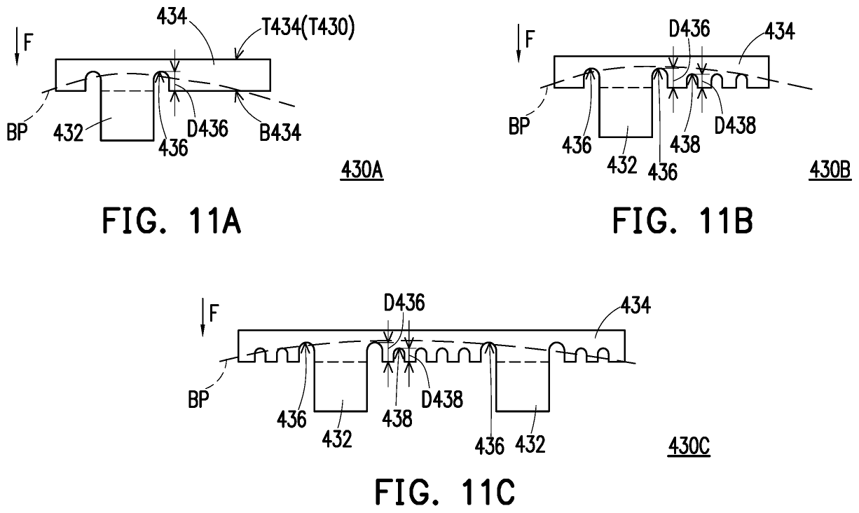

FIGS. 11A to 11C schematically illustrate various embodiments of the heat dissipation component in accordance with some embodiments of the disclosure. In FIGS. 11A to 11C, heat dissipation components 430A, 430B and 430C are adapted to optionally replace the second heat dissipation component 230 depicted in the previous embodiments and include the material having higher heat conductivity than the material for the first heat dissipation components 210 and 410. For example, the heat dissipation components 430A, 430B and 430C has a thermal conductivity greater than 200 W/m*K, for example, 800 W/m*K, greater than 1,000 W/m*K or higher. In some embodiments, a material of each of the heat dissipation components 430A, 430B and 430C include a super thermal conductive material such as silver diamond (AgD), diamond-like carbon (DLC), the like or a combination thereof.

The heat dissipation component 430A in FIG. 11A includes a first portion 432 and a second portion 434. The first portion 434 is a protruding portion from the second portion 434. The second portion 434 has a top surface 434A that is also the top surface T430 of the heat dissipation component 430 and a bottom surface B434 opposite to the top surface 430A. The first portion 432 is protruded from the bottom surface B434 of the second portion 434 to form the protruding portion. The heat dissipation component 430A further has notches 436 formed at the bottom surface B434 of the second portion 434. The notches 436 is positioned adjacent to the first portion 432. A depth D436 of the notch 430 is smaller than a distance from the top surface T434 to the bottom surface B434 so that the second portion 434 continuously extend through the notches 436. In some embodiments, the material of the heat dissipation component 430A is brittle and the notches 436 serve as a buffer structure for preventing the heat dissipation component 430A from cracked and/or broken. For example, when suffering a stress F, the notches 436 allows the heat dissipation component 430A to slightly bend along the bending path BP, so that the heat dissipation component 430A would not crack or break under the stress F.

The heat dissipation component 430B in FIG. 11B is similar to the heat dissipation component 430A and includes a first portion 432 and a second portion 434. The heat dissipation component 430B has various types of notches, such as the notches 436 and the notches 438 formed at the bottom of the second portion 434. The notches 436 are more adjacent to the first portion 432 than the notches 438. In addition, the notches 438 extends in a depth D438 smaller than the depth D436 of the notches 436. The material of the heat dissipation component 430B is brittle and the notches 436 and 438 serve as a buffer structure for preventing the heat dissipation component 430B from cracked and/or broken. For example, when suffering a stress F, the notches 436 and 438 allows the heat dissipation component 430B to slightly bend along the bending path BP, so that the heat dissipation component 430B would not crack or break under the stress F.

The heat dissipation component 430C in FIG. 11C is similar to the heat dissipation component 430A and includes two first portions 432 and a second portion 434. The heat dissipation component 430C has various types of notches, such as the notches 436 and the notches 438 formed at the bottom of the second portion 434. The notches 436 are more adjacent to the first portions 432 than the notches 438. In addition, the notches 438 extends in a depth D438 smaller than the depth D436 of the notches 436. The material of the heat dissipation component 430B is brittle and the notches 436 and 438 serve as a buffer structure for preventing the heat dissipation component 430C from cracked and/or broken. For example, when suffering a stress F, the notches 436 and 438 allows the heat dissipation component 430C to slightly bend along the bending path BP, so that the heat dissipation component 430C would not crack or break under the stress F.

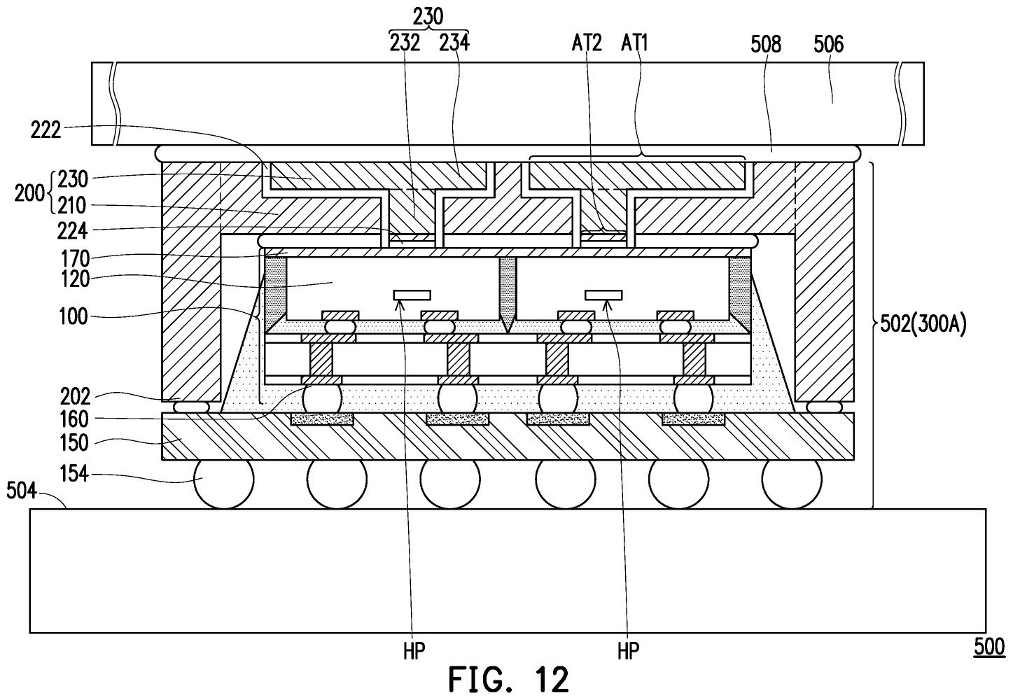

FIG. 12 schematically illustrates an electronic device in accordance with some embodiments of the disclosure. An electronic device 500 includes a 3D semiconductor package 502, a substrate 504 and a heat dissipation solution 506. The 3D semiconductor package 502 has the same structure as the 3D semiconductor package 300A in the embodiment and is optionally replaced by any of the 3D semiconductor packages 300B and 300C. Specifically, the 3D semiconductor package 502 includes a semiconductor package 100, a package substrate 150, and a heat dissipation unit 200. The semiconductor package 100 is bonded to the package substrate 150 through the conductive connectors 160. The heat dissipation unit 200 includes the first heat dissipation component 210 attached to the package substrate 150 through the adhesive 202 and attached to the semiconductor package 100 through the thermal interface material 190, and the second heat dissipation component 230 attached to the first heat dissipation component 210 through the first interface material 222 and attached to the semiconductor package 100 through the semiconductor package 100 through the second interface material 224. The package substrate 150 is bonded to the substrate 504 through the external connector 154. In addition, the heat dissipation solution 506 is attached to the 3D semiconductor package 502 through a further thermal interface material 508.

The substrate 504 includes a circuit substrate, or the like. The semiconductor components 120 packaged in the 3D semiconductor package 502 is electrically connected to the substrate 504 through at least the package substrate 150. In some embodiments, the substrate 504 is a system board, such as a PCB, of the electronic device 500. The heat dissipation solution 506 includes one or more heat dissipation structures. In some embodiments, the heat dissipation solution 506 includes heat pipe assembled therein for heat dissipation. In some embodiments, the heat dissipation solution 506 includes a vapor chamber such as a cooling chamber. The heat dissipation solution 506 dissipates the heat from the heat dissipation unit 200. In some embodiments, the heat dissipation solution 506 adopts an active type of heat dissipation technique to provide a high heat dissipation efficiency.

In some embodiments, the heat dissipation solution 506 is attached to the heat dissipation unit 200 by placing the heat dissipation solution 506 on the heat dissipation unit 200. The heat dissipation solution 506 is tightly attached to the heat dissipation unit 200 through the thermal interface material 508 so that a tress towards the substrate 504 is optionally applied to the heat dissipation unit 200. In some embodiments, the second heat dissipation component 230 is more rigid and/or fragile than the first heat dissipation component 210 and the first interface material 222 between the first heat dissipation component 210 and the second heat dissipation component 230 provides a buffer to prevent the second heat dissipation component 230 from cracked and/or broken under the stress.

The second heat dissipation component 230 includes a first portion 232 attached to and closer to the semiconductor component 120 of the semiconductor package 100 and a second portion 234 attached to and closer to the heat dissipation solution 506. The second portion 234 has a larger lateral dimension than the first portion 232 so that the area AT1 of the second heat dissipation component 230 attached to the semiconductor component 120 is smaller than the area AT2 of the second heat dissipation component 230 attached to the heat dissipation solution 506.

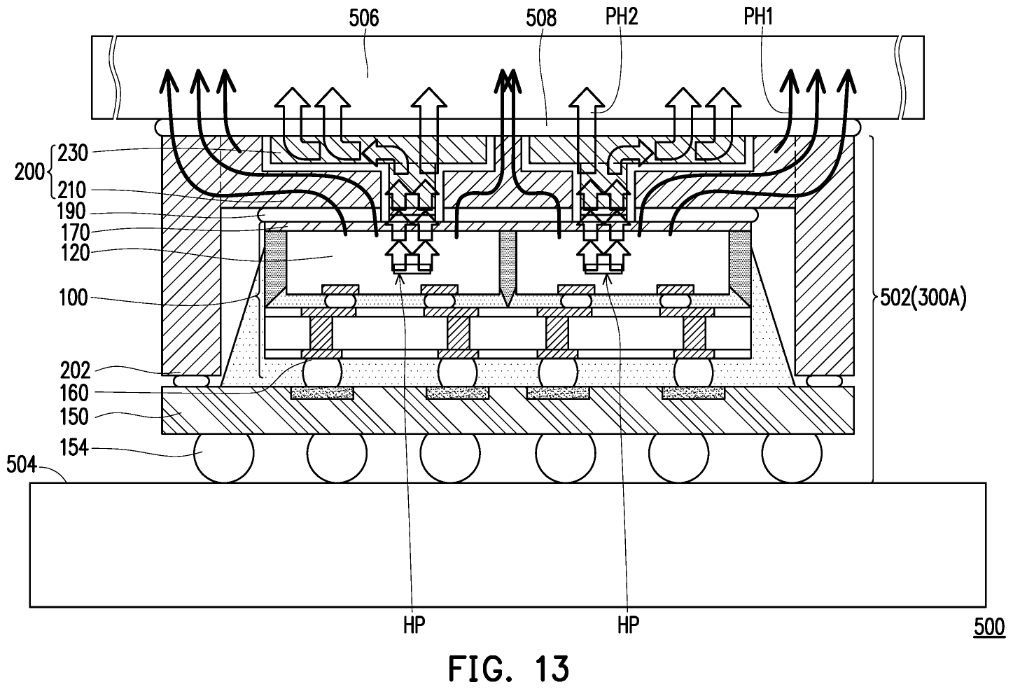

As shown in FIG. 13, the first heat dissipation component 210 provides a heat dissipation path PH1 and the second heat dissipation component 230 provides a heat dissipation path PH2. In some embodiments, the second heat dissipation component 230 has a thermal conductivity greater than the first heat dissipation component 210. Therefore, the second heat dissipation component 230 efficiently spreads the heat laterally and vertically from the area AT1 to the area AT2. The heat dissipation solution 506 further efficiently dissipates the heat from the first heat dissipation component 210 and the second heat dissipation component 230. Accordingly, the heat generated in the semiconductor components 120 of the semiconductor package 100 is efficiently dissipated to prevent from the damage and/or failure caused by heat. In some embodiments, the semiconductor components 120 of the semiconductor package 100 includes one or more hot spot regions HP and the second heat dissipation component 230 is located overlapping the hot spot regions HP. For example, the area AT1 of the second heat dissipation component 230 overlaps one of the hot spot regions HP. The hot spot region HP is the region that generates heat faster and/or more than other regions during operation of the semiconductor component 120. In light of the second heat dissipation component 230, the heat concentrated at the hot spot regions HP is dissipated in a faster rate than other regions so that heat concentration effect at the hot spot regions HP is mitigated. Therefore, failure or damage of the semiconductor components 120 due to an overheat effect is prevented to ensure the operation and the lifetime of the electronic device 500.

During the operation of the semiconductor components 120, the temperature of the second heat dissipation component 230 is increased due to the heat from the semiconductor component 120. In some embodiments, the first interface material 222 between the first heat dissipation component 210 and the second heat dissipation component 230 becomes softer and/or easier to be compressed at a higher temperature range such as 40° C. to 60° C. Accordingly, the second heat dissipation component 230 is likely to be push down by the thermal dissipation solution 506 to be more tightly attached to the semiconductor component 120 due to the soften of the first interface material 222. The thermal transmission between the semiconductor component 120 and the second heat dissipation component 230 is enhanced so as to achieve a better heat dissipation effect.

In some embodiments, the second heat dissipation component 230 and the first heat dissipation component 210 have greater thermal conductivity than the first interface material 222. The heat in the second heat dissipation component 230 is mostly transmitted within the second heat dissipation component 230 rather than transmitted to the first heat dissipation component 210. Accordingly, the heat of the second heat dissipation component 230 is mostly dissipated through area AT2 without laterally transmitted to the first heat dissipation component 210, which prevents the heat on the second heat dissipation component 230 from return to the 3D semiconductor package 502. In addition, the heat dissipation solution 506 optionally adopts an active type of heat dissipation technique such that the dissipation efficiency of the heat dissipation solution 506 is sufficiently to take away the heat from the first heat dissipation component 210 and the second heat dissipation component 230 to prevent the heat of the first heat dissipation component 210 and the second heat dissipation component 230 from returned to the semiconductor component 120.

In light of the above, the 3D semiconductor package in accordance with some embodiments of the disclosure includes a heat dissipation unit have two heat dissipation components, such as the first heat dissipation component and the second heat dissipation component. The first heat dissipation component has a through structure for accommodating the second heat dissipation component and the second heat dissipation component has better heat conductivity than the first heat dissipation component. The heat dissipation unit provides improved heat dissipation effect to facilitate the operation and lifetime of the semiconductor components in the 3D semiconductor package. In some embodiments, the first heat dissipation component and the second heat dissipation components are attached through a first interface material that have various properties at different temperature ranges. The softer and/or easier to be compressed state of the first interface material at higher temperature range helps to improve the attachment of the second heat dissipation component to the semiconductor component so that the heat dissipation effect between the second heat dissipation component and the semiconductor component is further ensured at higher temperature range. In some embodiments, the second heat dissipation component is attached to the semiconductor component through a second interface material that provides a good thermal interface so that the heat dissipation of semiconductor component through the second heat dissipation component is efficient.

In accordance with an embodiment, a 3D semiconductor package includes a package substrate; a semiconductor package bonded to the package substrate; a heat dissipation unit attached to the semiconductor package, wherein the heat dissipation unit comprises a first heat dissipation component and a second heat dissipation component attached to the first heat dissipation component; and a first interface material disposed between the first heat dissipation component and the second heat dissipation component, wherein the first interface material is a phase change material. The first interface material is softer at a first temperature range than at a second temperature range, and the first temperature is higher than the second temperature range. A second interface material is further included, and the second heat dissipation component is attached to the semiconductor package through the second interface material different from the first interface material. The first heat dissipation component has a through structure and the second heat dissipation component is inserted in the through structure. The first heat dissipation component includes a structure surface defining the through structure, the second heat dissipation component includes an embedded surface and the embedded surface conforms to the structure surface. The second heat dissipation component includes a first portion and a second portion, and the first portion is more adjacent to the semiconductor package than the second portion. A lateral dimension of the first portion is smaller than a lateral dimension of the second portion. The second heat dissipation component has a thermal conductivity greater than the first heat dissipation component. The first heat dissipation component includes a plate portion attached to the semiconductor package and a peripheral portion attached to the package substrate through an adhesive. A peripheral component is further included and attached to the package substrate and laterally surrounding the semiconductor package. The peripheral component is spaced from the first heat dissipation component by a gap.

In accordance with another embodiment, a 3D semiconductor package includes a package substrate; a semiconductor package bonded to the package substrate; and a heat dissipation unit attached to the semiconductor package, wherein the heat dissipation unit comprises a first heat dissipation component and a second heat dissipation component attached to the first heat dissipation component, and the second heat dissipation component has a thermal conductivity greater than the first heat dissipation component. The first heat dissipation component has a through structure and the second heat dissipation component is inserted in the through structure. The first heat dissipation component includes a structure surface defining the through structure, the second heat dissipation component includes an embedded surface and the embedded surface conforms to the structure surface. A top surface of the second heat dissipation component is higher than or equal to a top surface of the first heat dissipation component. The second heat dissipation component includes a first portion and a second portion, and the first portion is more adjacent to the semiconductor package than the second portion. A lateral dimension of the first portion is smaller than a lateral dimension of the second portion.

In accordance with yet another embodiment, a 3D semiconductor package includes a package substrate; a semiconductor package bonded to the package substrate; and a heat dissipation unit attached to the semiconductor package, wherein the heat dissipation unit comprises a first heat dissipation component having a through structure and a second heat dissipation component inserted in the through structure. The through structure has a lateral dimension gradually increased from a bottom end to a top end further away from the semiconductor package than the bottom end. The second heat dissipation component has a structure compensating the through structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A 3D semiconductor package comprising:
a package substrate;
a semiconductor package bonded to the package substrate;
a heat dissipation unit attached to the semiconductor package, wherein the heat dissipation unit comprises a first heat dissipation component and a second heat dissipation component attached to the first heat dissipation component; and
a first interface material disposed between the first heat dissipation component and the second heat dissipation component, wherein the first interface material is a phase change material.

2. The 3D semiconductor package of claim 1, wherein the first interface material is softer at a first temperature range than at a second temperature range, and the first temperature range is higher than the second temperature range.

3. The 3D semiconductor package of claim 1, further comprising a second interface material, wherein the second heat dissipation component is attached to the semiconductor package through the second interface material different from the first interface material.

4. The 3D semiconductor package of claim 1, wherein the first heat dissipation component has a through structure and the second heat dissipation component is inserted in the through structure.

5. The 3D semiconductor package of claim 4, wherein the first heat dissipation component includes a structure surface defining the through structure, the second heat dissipation component includes an embedded surface and the embedded surface conforms to the structure surface.

6. The 3D semiconductor package of claim 1, wherein the second heat dissipation component includes a first portion and a second portion, and the first portion is more adjacent to the semiconductor package than the second portion.

7. The 3D semiconductor package of claim 6, wherein a lateral dimension of the first portion is smaller than a lateral dimension of the second portion.

8. The 3D semiconductor package of claim 1, wherein the second heat dissipation component has a thermal conductivity greater than the first heat dissipation component.

9. The 3D semiconductor package of claim 1, wherein the first heat dissipation component comprises a plate portion attached to the semiconductor package and a peripheral portion attached to the package substrate through an adhesive.

10. The 3D semiconductor package of claim 1, further comprising a peripheral component attached to the package substrate and laterally surrounding the semiconductor package.

11. The 3D semiconductor package of claim 10, wherein the peripheral component is spaced from the first heat dissipation component by a gap.

12. A 3D semiconductor package, comprises:
a package substrate;
a semiconductor package bonded to the package substrate; and
a heat dissipation unit attached to the semiconductor package, wherein the heat dissipation unit comprises a first heat dissipation component and a second heat dissipation component attached to the first heat dissipation component, and the second heat dissipation component has a thermal conductivity greater than the first heat dissipation component.

13. The 3D semiconductor package of claim 12, wherein the first heat dissipation component has a through structure and the second heat dissipation component is inserted in the through structure.

14. The 3D semiconductor package of claim 13, wherein the first heat dissipation component includes a structure surface defining the through structure, the second heat dissipation component includes an embedded surface and the embedded surface conforms to the structure surface.

15. The 3D semiconductor package of claim 12, wherein a top surface of the second heat dissipation component is higher than or coplanar to a top surface of the first heat dissipation component.

16. The 3D semiconductor package of claim 12, wherein the second heat dissipation component includes a first portion and a second portion, and the first portion is more adjacent to the semiconductor package than the second portion.

17. The 3D semiconductor package of claim 16, wherein a lateral dimension of the first portion is smaller than a lateral dimension of the second portion.

18. A 3D semiconductor package, comprises:
a package substrate;
a semiconductor package bonded to the package substrate; and
a heat dissipation unit attached to the semiconductor package, wherein the heat dissipation unit comprises a first heat dissipation component having a through structure and a second heat dissipation component inserted in the through structure.

19. The 3D semiconductor package of claim 18, wherein the through structure has a lateral dimension gradually increased from a bottom end to a top end further away from the semiconductor package than the bottom end.

20. The 3D semiconductor package of claim 19, wherein the second heat dissipation component has a structure compensating the through structure.
